(19) United States
(12) Patent Application Publication
(10) Pub. No.: US 2016/0216602 A1
(43) Pub. Date: Jul. 28, 2016

(54) MASK AND MANUFACTURING METHOD FOR LIQUID CRYSTAL DISPLAY USING THE SAME

(71) Applicant: Samsung Display Co., Ltd., Yongin-City (KR)

(72) Inventors: Seong Woon CHOI, Suwon-si (KR); Min KANG, Seoul (KR); Jong Hyeok RYU, Seoul (KR); Sung-Mo KANG, Cheonan-si (KR); Keun Ha KIM, Asan-si (KR); Bong-Yeon KIM, Seoul (KR); Soon Young KIM, Suwon-si (KR); In Ho KIM, Asan-si (KR); Soo Jin PARK, Seoul (KR); Yong SON, Suwon-si (KR); Min Jee LEE, Cheonan-si (KR); Yun ku JUNG, Asan-si (KR); Hye Ran JEONG, Busan (KR); Chung Heon HAN, Asan-si (KR)

(21) Appl. No.: 14/819,270

(22) Filed: Aug. 5, 2015

(30) Foreign Application Priority Data
Jan. 26, 2015 (KR) 10-2015-0012144

(51) Int. Cl. G03F 1/50; G02F 1/1339; G02F 1/1362

(52) U.S. Cl. CPC G03F 1/50; G02F 1/136286; G02F 1/13394; G02F 2001/136295; G02F 2001/13396

(57) ABSTRACT

A mask including: a transparent substrate and a light blocking layer thereon. The transparent substrate includes a first transmitting portion and a second transmitting portion each configured to pass light, and a light blocking portion configured to block light. The first transmitting portion includes a first transmitting region configured to pass light and a first light blocking region configured to block light, and area centers of the first transmitting region and the first light blocking region substantially coincide. The second transmitting portion includes a second transmitting region configured to pass light and a second light blocking region configured to block light, and area centers of the second transmitting region and the second light blocking region substantially coincide, so that the first transmitting portion is configured to pass light of a greater intensity and the second transmitting portion is configured to pass light of a lesser intensity.

### CROSS-REFERENCE TO RELATED APPLICATION

This application claims priority to, and the benefit of, Korean Patent Application No. 10-2015-0012144 filed in the Korean Intellectual Property Office on Jan. 26, 2015, the entire contents of which are incorporated herein by reference.

### BACKGROUND

(a) Technical Field

Embodiments of the present invention relate generally to liquid crystal displays. More specifically, embodiments of the present invention relate to a mask and a manufacturing method for a liquid crystal display using the same.

(b) Description of the Related Art

Flat panel display devices have largely replaced cathode ray tube display devices due to their light weight and a thin profile. Different types of flat panel display devices include, as representative examples, a liquid crystal display device (LCD) and an organic light emitting diode display device (OLED).

The LCD, which is one of the most common types of flat panel displays currently in use, includes two display panels with field generating electrodes such as a pixel electrode and a common electrode, with a liquid crystal layer interposed therebetween.

The LCD generates an electric field in the liquid crystal layer by applying voltage to the field generating electrodes, and determines the direction of liquid crystal molecules of the liquid crystal layer by the generated electric field, thus controlling polarization of incident light so as to display images.

The two display panels of the LCD maintain a gap using a spacer. Recently, as demand for higher resolution displays has increased, components constituting the LCD, including spacers, must be made smaller. In order to reduce the size of the spacer, the spacer may be formed by, for example, using a mask with a Fresnel pattern.

The above information disclosed in this Background section is only for enhancement of understanding of the background of the invention and therefore it may contain information that does not form the prior art that is already known in this country to a person of ordinary skill in the art.

### SUMMARY

Embodiments of the present invention provide a mask and a method of manufacturing a liquid crystal display using the same, that can result in simultaneously forming a main spacer and a sub spacer having different lengths.

An exemplary embodiment of the present invention provides a mask including: a transparent substrate; and a light blocking layer disposed on the transparent substrate. The transparent substrate includes a first transmitting portion and a second transmitting portion each configured to pass light therethrough, and a light blocking portion configured to block light. The first transmitting portion includes a first transmitting region configured to pass light therethrough and a first light blocking region configured to block light, and a center of area of the first transmitting region and a center of area of the first light blocking region substantially coincide. The second transmitting portion includes a second transmitting region configured to pass light therethrough and a second light blocking region configured to block light, and a center of area of the second transmitting region and a center of area of the second light blocking region substantially coincide. The first transmitting portion is configured to pass light having a first intensity, and the second transmitting portion is configured to pass light having a second intensity, the first intensity being greater than the second intensity.

The light blocking layer may be disposed on the light blocking portion, the first light blocking region, and the second light blocking region.

The second transmitting portion may further include a blocking member configured to block light, and the blocking member may be disposed on parts of both the second transmitting region and the second light blocking region.

The blocking member may have a cross shape including a first portion and a second portion oriented substantially perpendicular to the first portion.

The blocking member may have a center and members extending radially from the center.

The blocking member may have a plurality of fan-shaped structures spaced apart from each other.

Another exemplary embodiment of the present invention provides a method of manufacturing a liquid crystal display, including: forming a gate line on a first insulation substrate; forming a gate insulating layer on the first insulation substrate and the gate line; forming a semiconductor on the gate insulating layer; forming a data line on the semiconductor, the data line including a source electrode and a drain electrode facing the source electrode; forming a passivation layer on the gate insulating layer, the data line, and the drain electrode; forming a lower alignment layer on the passivation layer; forming a photosensitive material layer on the lower alignment layer; forming a first curing region and a second curing region by exposing the photosensitive material layer using a mask, so that the second curing region has a size smaller than a size of the first curing region; and forming a main spacer and a sub spacer by developing the photosensitive material layer. The length of the main spacer is larger than that of the sub spacer. The mask includes a transparent substrate and a light blocking layer disposed on the transparent substrate, where the transparent substrate includes a first transmitting portion and a second transmitting portion each configured to pass light therethrough, and a light blocking portion configured to block light. The forming a first curing region and a second curing region further comprises forming the first curing region by passing light through the first transmitting portion, and forming the second curing region by passing light through the second transmitting portion.

The forming a main spacer and a sub spacer may further comprise forming the main spacer from the first curing region and forming the sub spacer from the second curing region.

The photosensitive material layer may have negative photosensitivity.

According to the exemplary embodiment of the present invention, it is possible to simultaneously form a main spacer and a sub spacer having different lengths by using a mask including a first transmitting portion and a second transmitting portion having different intensities of transmitted light.

### BRIEF DESCRIPTION OF THE DRAWINGS

FIG. 1 is an equivalent circuit diagram of one pixel of a liquid crystal display according to an exemplary embodiment of the present invention.

FIG. 2 is a layout view of one pixel of the liquid crystal display according to the exemplary embodiment of the present invention.

FIG. 3 is a diagram illustrating an example of a cross section of a liquid crystal display taken along line III-III of FIG. 2.

FIG. 4 is a diagram illustrating a manufacturing method for a liquid crystal display according to an exemplary embodiment of the present invention.

FIG. 5 is a diagram schematically illustrating a plan view of a mask according to the exemplary embodiment of the present invention.

FIG. 6 is a diagram illustrating an example of a cross section of the mask of FIG. 5 taken along line VI-VI.

FIG. 7 is a diagram schematically illustrating a plan view of a mask according to another exemplary embodiment of the present invention.

FIG. 8 is a diagram schematically illustrating a plan view of a mask according to yet another exemplary embodiment of the present invention.

FIG. 9 is a diagram schematically illustrating a manufacturing method for a liquid crystal display according to an exemplary embodiment of the present invention.

FIG. 10 is a diagram illustrating an example of a cross section of a liquid crystal display according to another exemplary embodiment of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Accordingly, the drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto.

In the drawings, the thickness of layers, films, panels, regions, etc., are exaggerated for clarity. In the drawings, for understanding and ease of description, the thickness of some layers and areas is exaggerated. The various Figures are thus not to scale. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. Further, throughout the specification, the word “on” means positioning on or below the object portion, but does not essentially mean positioning on the upper side of the object portion based on a gravity direction.

All numerical values are approximate, and may vary. All examples of specific materials and compositions are to be taken as nonlimiting and exemplary only. Other suitable materials and compositions may be used instead.

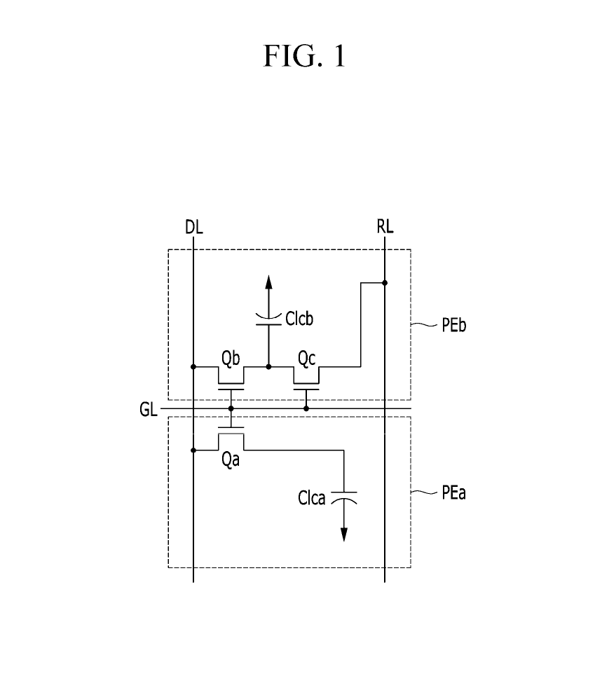

First, a liquid crystal display according to an exemplary embodiment of the present invention will be described with reference to FIGS. 1 to 3.

FIG. 1 is an equivalent circuit diagram of one pixel of a liquid crystal display according to an exemplary embodiment of the present invention. Referring to FIG. 1, one pixel PX of the liquid crystal display according to the exemplary embodiment includes a plurality of signal lines including a gate line GL transferring a gate signal, a data line DL transferring a data signal, and a reference voltage line RL transferring a divided reference voltage, first, second, and third switching elements Qa, Qb, and Qc connected to the plurality of signal lines, and first and second liquid crystal capacitors Clca and Clcb.

The first and second switching elements Qa and Qb are connected to the gate line GL and the data line DL, respectively, and the third switching element Qc is connected to an output terminal of the second switching element Qb and the reference voltage line RL.

The first switching element Qa and the second switching element Qb are three-terminal elements such as a thin film transistor, and control terminals thereof are connected to the gate line GL, input terminals thereof are connected to the data line DL, an output terminal of the first switching element Qa is connected to the first liquid crystal capacitor Clca, and an output terminal of the second switching element Qb is connected to the second liquid crystal capacitor Clcb and the input terminal of the third switching element Qc.

The third switching element Qc is also a three-terminal element such as a thin film transistor, and a control terminal thereof is connected to the gate line GL, an input terminal thereof is connected to the second liquid crystal capacitor Clcb, and an output terminal thereof is connected to the reference voltage line RL.

When a gate-on signal is applied to the gate line GL, the first switching element Qa, the second switching element Qb, and the third switching element Qc which are connected to the gate line GL are turned on. As a result, the data voltage applied to the data line DL is applied to a first subpixel electrode PEa and a second subpixel electrode PEb through the turned-on first switching element Qa and second switching element Qb. In this case, the data voltages applied to the first subpixel electrode PEa and the second subpixel electrode PEb are the same as each other, and the first liquid crystal capacitor Clca and the second liquid crystal capacitor Clcb are charged with the same value by a difference between the common voltage and the data voltage. Simultaneously, the voltage charged into the second liquid crystal capacitor Clcb is divided through the turned-on third switching element Qc. As a result, a voltage value charging the second liquid crystal capacitor Clcb is decreased by a difference between the common voltage and the divided reference voltage. That is, the voltage charged into the first liquid crystal capacitor Clca is higher than the voltage charged into the second liquid crystal capacitor Clcb.

As such, the voltage charged into the first liquid crystal capacitor Clca and the voltage charged into the second liquid crystal capacitor Clcb are different from each other. Since the voltage of the first liquid crystal capacitor Clca and the voltage of the second liquid crystal capacitor Clcb are different from each other, tilt angles of liquid crystal molecules in the first subpixel and the second subpixel are different from each other, and as a result, luminance of two subpixels is different from each other. Accordingly, when the voltage of the first liquid crystal capacitor Clca and the voltage of the second liquid crystal capacitor Clcb are appropriately controlled, an image viewed from the side may be maximally approximated to an image viewed from the front, thereby improving side visibility.

In the illustrated exemplary embodiment, in order to vary the charged voltage in the first liquid crystal capacitor Clca and the charged voltage in the second liquid crystal capacitor Clcb, the third switching element Qc connected to the second liquid crystal capacitor Clcb and the reference voltage line RL is included, but in the case of a liquid crystal display according to another exemplary embodiment of the present invention, the second liquid crystal capacitor Clcb may have its voltage varied by being connected to a step-down capacitor. In such an embodiment, the third switching element would include a first terminal connected to a step-down gate line, a second terminal connected to the second liquid crystal capacitor Clcb, and a third terminal connected to the step-down capacitor, and as a result, charged voltages between the first liquid crystal capacitor Clca and the second liquid crystal capacitor Clcb may be made different, by charging some of a charge amount charged in the second liquid crystal capacitor Clcb into the step-down capacitor.

Further, in the case of a liquid crystal display according to another exemplary embodiment of the present invention, the first liquid crystal capacitor Clca and the second liquid crystal capacitor Clcb are connected to different data lines to receive different data voltages, and as a result, the charging voltages between the first liquid crystal capacitor Clca and the second liquid crystal capacitor Clcb may be differently set.

In addition, by various different methods, the charging voltages between the first liquid crystal capacitor Clca and the second liquid crystal capacitor Clcb may be differently set. That is, embodiments of the invention contemplate any configurations and methods for charging the two liquid crystal capacitors Clca, Clcb with arbitrary voltages.

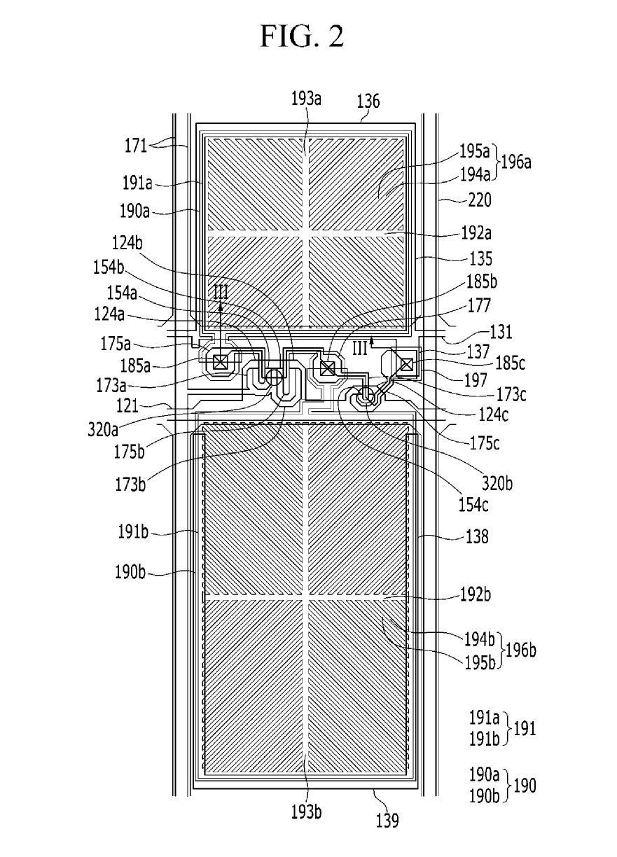

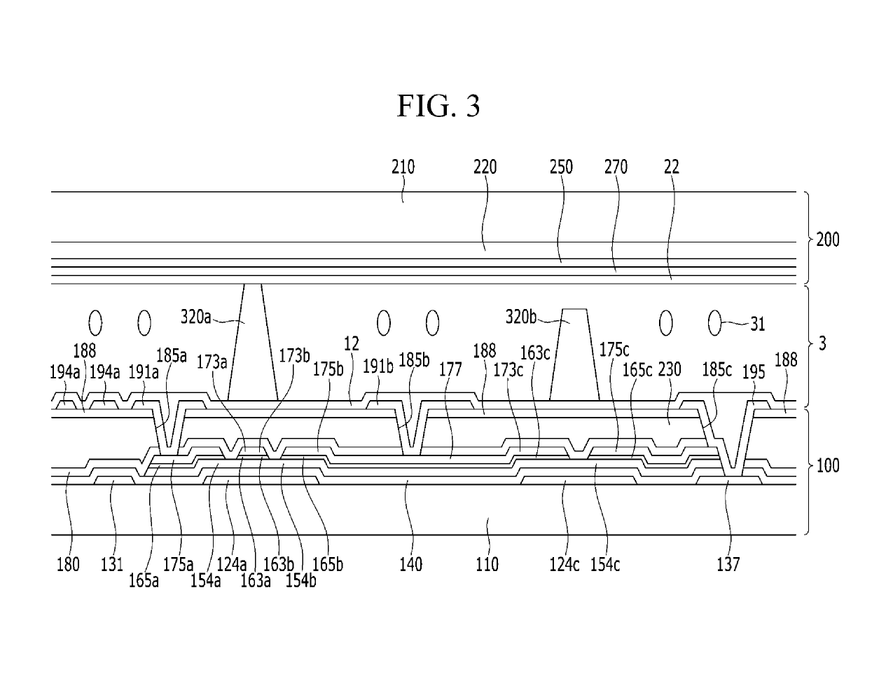

Next, a structure of the liquid crystal display according to the exemplary embodiment illustrated in FIG. 1 will be further described with reference to FIGS. 2 and 3.

FIG. 2 is a layout view of one pixel of a liquid crystal display according to the exemplary embodiment of the present invention. FIG. 3 is a diagram illustrating an example of a cross section of the liquid crystal display of FIG. 2 taken along line III-III.

Referring to FIGS. 2 and 3, the liquid crystal display according to the exemplary embodiment includes a first display panel 100 and a second display panel 200 facing each other, and a liquid crystal layer 3 interposed between the two display panels 100 and 200.

Hereinafter, the first display panel 100 will be described.

A gate line 121 and a reference voltage line 131 are disposed on a first insulation substrate 110 made of transparent glass or plastic.

The gate line 121 mainly extends in a horizontal direction and transfers a gate signal, and includes a first gate electrode 124a, a second gate electrode 124b, and a third gate electrode 124c. Further, the data line 121 includes a wide end portion (not illustrated) for connection with another layer or an external driving circuit.

The reference voltage line 131 mainly extends in a horizontal direction and transfers a predetermined voltage such as a reference voltage, and includes first storage electrodes 135 and 136 and a reference electrode 137. The first storage electrodes 135 and 136 surround a first subpixel electrode 191a to be described below, and the reference electrode 137 protrudes toward gate line 121. Further, the reference voltage line 131 includes second storage electrodes 138 and 139 surrounding a second subpixel electrode 191b to be described below. Although not illustrated in FIG. 1, a horizontal portion 136 of the first storage electrodes 135 and 136 may be connected with a horizontal portion 139 of the second storage electrodes 138 and 139 of a previous pixel by an integrated wire.

A gate insulating layer 140 is disposed on the first insulation substrate 110, the gate line 121, and the reference voltage line 131. Next, a first semiconductor 154a, a second semiconductor 154b, and a third semiconductor 154c which are made of amorphous or polycrystalline silicon are disposed on the gate insulating layer 140. Further, the first semiconductor 154a, the second semiconductor 154b, and the third semiconductor 154c may be made of oxide semiconductors.

A plurality of pairs of ohmic contacts 163a, 165a, 163b, 165b, 163c, and 165c is disposed on the first semiconductor 154a, the second semiconductor 154b, and the third semiconductor 154c, respectively. The ohmic contacts 163a, 165a, 163b, 165b, 163c, and 165c may be made of silicide or n+ hydrogenated amorphous silicon in which an n-type impurity is doped at a high concentration. Further, when the first semiconductor 154a, the second semiconductor 154b, and the third semiconductor 154c are made of oxide semiconductors, the ohmic contacts 163a, 165a, 163b, 165b, 163c, and 165c may be omitted.

A data conductor 171, 173a, 173b, 173c, 175a, 175b, and 175c including a plurality of data lines 171 including a first source electrode 173a and a second source electrode 173b, a first drain electrode 175a, a second drain electrode 175b, a third source electrode 173c, a third drain electrode 175c is formed on the ohmic contacts 163a, 165a, 163b, 165b, 163c, and 165c and the gate insulating layer 140.

The data lines 171 transfer data signals and mainly extend in a vertical direction to cross the gate lines 121 and the reference voltage line 131. The first source electrode 173a and the first drain electrode 175a overlap the first semiconductor 154a, the second source electrode 173b and the second drain electrode 175b overlap the second semiconductor 154b, and the third source electrode 173c and the third drain electrode 175c overlap the third semiconductor 154c. The first source electrode 173a and the first drain electrode 175a face each other over the first gate electrode 124a, the second source electrode 173b and the second drain electrode 175b face each other over the second gate electrode 124b, and the third source electrode 173c and the third drain electrode 175c face each other over the third gate electrode 124c. The second drain electrode 175b includes a widened extension 177 connected to the third source electrode 173c. However, the present invention is not limited thereto, and the shape and the layout of the data line 171 including the first, second, and third electrodes 175a, 175b, and 175c may take on any shape and configuration.

Further, the data line 171 includes a wide end portion (not illustrated) for connection with another layer or an external driving circuit.

The first gate electrode 124a, the first source electrode 173a, and the first drain electrode 175a form a first thin film transistor (TFT) Qa together with the first semiconductor 154a, and a channel of the first TFT Qa is formed in the first semiconductor 154a between the first source electrode 173a and the first drain electrode 175a. Similarly, the second gate electrode 124b, the second source electrode 173b, and the second drain electrode 175b form a second thin film transistor Qb together with the second semiconductor 154b, and a channel of the second thin film transistor Qb is formed in the second semiconductor 154b between the second source electrode 173b and the second drain electrode 175b. Further, the third gate electrode 124c, the third source electrode 173c, and the third drain electrode 175c form a third thin film transistor Qc together with the third semiconductor 154c, and a channel of the third thin film transistor Qc is formed in the third semiconductor 154c between the third source electrode 173c and the third drain electrode 175c.

A passivation layer 180 is disposed on the data conductor 171, 173a, 173b, 173c, 175a, 175b, and 175c, and the exposed portions of the first, second and third semiconductors 154a, 154b, and 154c. The passivation layer 180 may be made of an inorganic insulating material such as silicon nitride or silicon oxide. The passivation layer 180 may prevent a pigment of a color filter 230 to be described below from flowing into the exposed portions of the semiconductors 154a, 154b, and 154c.

The color filter 230 is disposed on the passivation layer 180. The color filter 230 extends in a vertical direction between two adjacent data lines 171.

The color filter 230 may display one of a primary color such as red, green or blue. However, the color filter 230 may display any other color, such as one of cyan, magenta, yellow, or any white-based colors.

An overcoat 188 is disposed on the color filter 230. The overcoat 188 may be made of an inorganic insulating material such as silicon nitride or silicon oxide. The overcoat 188 may prevent the color filter 230 from being lifted and may also prevent the liquid crystal layer 3 from being contaminated due to an organic material such as a solvent flowing from the color filter 230, thereby preventing defects such as an afterimage which may be caused when a screen is driven.

A first contact hole 185a and a second contact hole 185b exposing the first drain electrode 175a and the second drain electrode 175b are formed in the passivation layer 180, color filter 230, and overcoat 188. Further, a third contact hole 185c exposing a part the reference electrode 137 and a part of the third drain electrode 175c is formed in the passivation layer 180, the color filter 230, the overcoat 188, and the gate insulating layer 140.

A pixel electrode 191 and a connecting member 197 are disposed on the overcoat 188 to be separated from each other. The pixel electrode 191 includes a first subpixel electrode 191a and a second subpixel electrode 191b which are separated from each other with the gate line 121 therebetween to be adjacent to each other in a column direction with the gate line 121 inbetween.

The pixel electrode 191 and the connecting member 197 may be made of a transparent material such as ITO or IZO. Further, the pixel electrode 191 and the connecting member 197 may also be made of a reflective metal such as aluminum, silver, chromium, or an alloy thereof.

The overall shapes of the first subpixel electrode 191a and the second subpixel electrode 191b are quadrangles, and the first subpixel electrode 191a and the second subpixel electrode 191b include cross stems defined by horizontal stems 192a and 192b and vertical stems 193a and 193b crossing the horizontal stems 192a and 192b, respectively.

Further, the pixel electrode 191 is divided into four domains by the horizontal stems 192a and 192b and the vertical stems 193a and 193b, and each domain includes a plurality of minute branch portions 196a and 196b. The minute branch portions 196a and 196b include minute branches 194a and 194b and minute slits 195a and 195b.

One of the minute branch portions 196a and 196b of each of the first subpixel electrode 191a and the second subpixel electrode 191b obliquely extends in an upper left direction from the horizontal stems 192a and 192b or the vertical stems 193a and 193b, and another of the minute branch portions 196a and 196b obliquely extends in an upper right direction from the horizontal stems 192a and 192b or the vertical stems 193a and 193b. Further, another one of the minute branch portions 196a and 196b obliquely extends in a lower left direction from the horizontal stems 192a and 192b or the vertical stems 193a and 193b, and the rest of the minute branch portions 196a and 196b obliquely extend in a lower right direction from the horizontal stems 192a and 192b or the vertical stems 193a and 193b.

Each of the minute branch portions 196a and 196b forms an angle of approximately 40° to 45° with the gate line 121 or the horizontal stems 192a and 192b. Particularly, the minute branch portion 196a included in the first subpixel electrode 191a may form an angle of approximately 40° with the horizontal stem 192a, and the minute branch portion 196b included in the second subpixel electrode 191b may form an angle of approximately 45° with the horizontal stem 192b. Further, the minute branch portions 196a and 196b of two adjacent domains may be perpendicular to each other.

The first subpixel electrode 191a is physically and electrically connected to the first drain electrode 175a through the first contact hole 185a. As a result, the first subpixel electrode 191a receives the data voltage from the first drain electrode 175a.

The second subpixel electrode 191b is physically and electrically connected to the second drain electrode 175b through the second contact hole 185b. As a result, the second subpixel electrode 191b receives the data voltage from the second drain electrode 175b.

The connecting member 197 electrically connects the reference electrode 137 and the third drain electrode 175c exposed by the third contact hole 185c.

A part of the data voltage applied to the second drain electrode 175b is divided through the third source electrode 173c, and as a result, a magnitude of the voltage applied to the first subpixel electrode 191a is larger than a magnitude of the voltage applied to the second subpixel electrode 191b. This case is a case where the voltages applied to the first subpixel electrode 191a and the second subpixel electrode 191b are positive (+). Alternatively, when the voltages applied to the first subpixel electrode 191a and the second subpixel electrode 191b are negative (−), the magnitude of the voltage applied to the first subpixel electrode 191a is smaller than a magnitude of the voltage applied to the second subpixel electrode 191b.

A lower alignment layer 12 is positioned on the overcoat 188, the pixel electrode 191, and the connecting member 197.

A main spacer 320a and a sub spacer 320b are disposed on the lower alignment layer 11. The main spacer 320a and the sub spacer 320b may be made of the same material, and lengths or heights thereof are different from each other. The length of the main spacer 320a is larger than that of the sub spacer 320b.

Next, the second display panel 200 will be described.

A light blocking member 220 is formed on a second insulation substrate 210 made of transparent glass or plastic.

The light blocking member 220 extends along the data line 171 and the gate line 121. A width of the light blocking member 220 may be larger than a width of the data line 171 and a width of the gate line 121. As such, the width of the light blocking member 220 is larger than the width of the data line 171 and the width of the gate line 121, and as a result, the light blocking member 220 may prevent light incident from the outside from being reflected from the metal surface of the data line 171. Light reflected from the surfaces of the data line 171 and the gate line 121 interferes with light passing through the liquid crystal layer 3. Thus, as the light blocking member 220 prevents such reflection, it prevents a contrast ratio of the liquid crystal display from deteriorating.

A planarization layer 250 is disposed on the light blocking member 220, a common electrode 270 is disposed on the planarization layer 250, and an upper alignment layer 22 is disposed on the common electrode 270.

The main spacer 320a contacts the second display panel 200. The main spacer 320a serves to uniformly maintain a gap between the first display panel 100 and the second display panel 200. The main spacer 320a may have elasticity and may be compressed by external force and then restored to an original state again. That is, it may return to its original shape once external stress or pressure is removed.

The sub spacer 320b is spaced apart from the second display panel 200. The sub spacer 320b contacts the second display panel 200 to distribute force applied to the main spacer 320a when external force having a predetermined value or more is applied to the main spacer 320a. As a result, the sub spacer 320b may prevent the main spacer 320a from being damaged by external forces greater than or equal to some predetermined value.

The lower alignment layer 12 and the upper alignment layer 22 may be formed by vertical alignment layers, and made of alignment materials such as polyamic acid, polysiloxane, and polyimide.

The liquid crystal layer 3 includes a plurality of liquid crystal molecules 31 having negative dielectric anisotropy, and the liquid crystal molecules 31 are aligned so that long axes thereof are substantially vertical (i.e. perpendicular) to the surfaces of the first and second display panels 100 and 200 while an electric field is not applied.

Further, the liquid crystal layer 3 may include prepolymer such as monomers cured by polymerization with light. The prepolymer may include a reactive mesogen polymerized by light such as ultraviolet rays.

Meanwhile, the prepolymer, such as monomers cured by polymerization via light, is included in the lower alignment layer 12 and the upper alignment layer 22. In this case, the prepolymer is not included in the liquid crystal layer 3.

The first subpixel electrode 191a and the second subpixel electrode 191b, to which the data voltages are applied, generate an electric field together with the common electrode 270 to determine directions of the liquid crystal molecules 31 of the liquid crystal layer 3 between the first display panel 100 and the second display panel 200. Luminance of light passing through the liquid crystal layer 3 varies according to the directions of the liquid crystal molecules 31 determined above, thus forming an image.

Hereinafter, a manufacturing method of the liquid crystal display according to the exemplary embodiment of the present invention will be described with reference to FIGS. 4 to 9 and FIGS. 1 and 2.

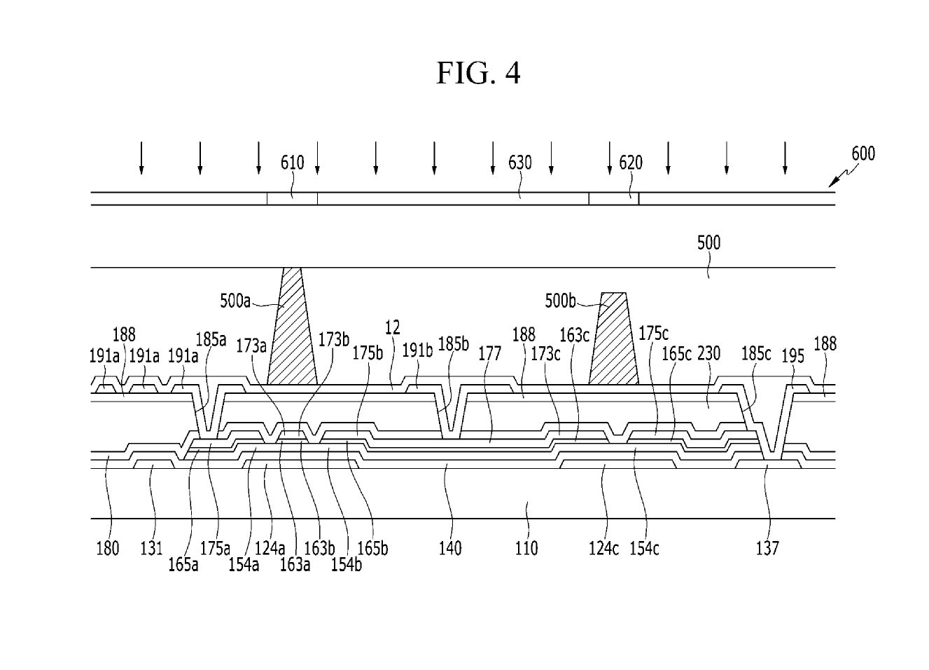

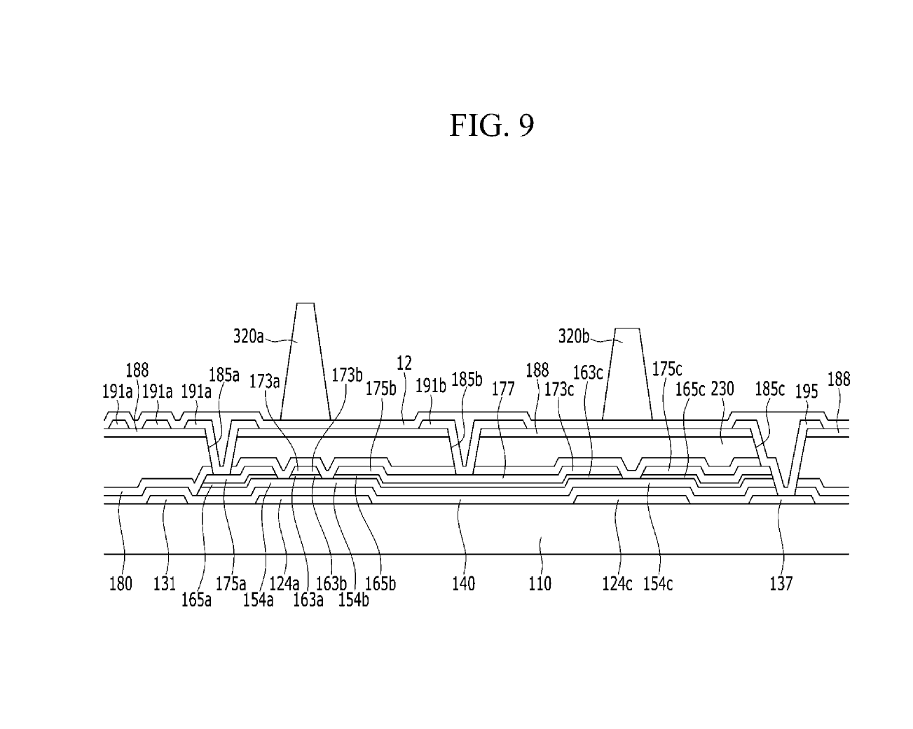

FIGS. 4 and 9 are diagrams illustrating a method of manufacturing a liquid crystal display according to an exemplary embodiment of the present invention.

Referring to FIG. 4, the gate line 121 and the reference voltage line 131 are formed on the first insulation substrate 110; the gate insulating layer 140 is formed on the first insulation substrate 110, the gate line 121, and the reference voltage line 131; and then the first semiconductor 154a, the second semiconductor 154b, and the third semiconductor 154c are formed on the gate insulating layer 140. Here, the gate line 121 includes the first gate electrode 124a, the second gate electrode 124b, and the third gate electrode 124c. The reference voltage line 131 includes the first storage electrodes 135 and 136, the reference electrode 137, and the second storage electrodes 138 and 139.

Next, a plurality of pairs of ohmic contacts 163a, 165a, 163b, 165b, 163c, and 165c is formed on the first semiconductor 154a, the second semiconductor 154b, and the third semiconductor 154c, respectively. Then, the third drain electrode 175c is formed on the ohmic contacts 163a, 165a, 163b, 165b, 163c, and 165c and the gate insulating layer 140, the data conductor 171, 173a, 173b, 173c, 175a, 175b, and 175c. Herein, the first semiconductor 154a, the second semiconductor 154b, the third semiconductor 154c, the ohmic contacts 163a, 165a, 163b, 165b, 163c, and 165c, and the data conductor 171, 173a, 173b, 173c, 175a, 175b, and 175c may be formed by using the same mask.

Next, the passivation layer 180 is formed on the gate insulating layer 140 and the data conductor 171, 173a, 173b, 173c, 175a, 175b, and 175c, the color filter 230 and the overcoat 188 are sequentially formed on the passivation layer 180, and then the first contact hole 185a, the second contact hole 185b, and the third contact hole 185c are formed. Here, the first contact hole 185a is formed in the passivation layer 180, the color filter 230, and the overcoat 188 to expose a part of the first drain electrode 175a. The second contact hole 185b is formed in the passivation layer 180, the color filter 230, and the overcoat 188 to expose a part of the second drain electrode 175b. The third contact hole 185c is formed in the passivation layer 180, the color filter 230, the overcoat 188, and the gate insulating layer 140 to expose a part of the reference electrode 137 and a part of the third drain electrode 175c.

Next, the pixel electrode 191 and the connecting member 197 are formed on the overcoat 188, and then the lower alignment layer 12 is formed on the overcoat 188, the pixel electrode 191, and the connecting member 197. Here, the pixel electrode 191 includes the first subpixel electrode 191a and the second subpixel electrode 191b which are separated from each other. The first subpixel electrode 191a is connected to the first drain electrode 175a through the first contact hole 185a, and the second subpixel electrode 191b is connected to the second drain electrode 175b through the second contact hole 185b. The connecting member 197 is separated from the pixel electrode 191 and connected to the reference electrode 137 and the third drain electrode 175c through the third contact hole 185c.

Next, a photosensitive material layer 500 is formed on the lower alignment layer 12, and then the photosensitive material layer 500 is exposed by using a mask 600. The photosensitive material layer 500 may have negative photosensitivity and ultraviolet rays may be used during exposure.

The mask 600 includes a first transmitting portion 610, a second transmitting portion 620, and a light blocking portion 630. During exposure, light passes through the first transmitting portion 610 and the second transmitting portion 620 to fall incident upon the photosensitive material layer 500. In this case, a first curing region 500a and a second curing region 500b are formed on the photosensitive material layer 500. The first curing region 500a is formed by the light passing through the first transmitting portion 610, and the second curing region 500b is formed by the light passing through the second transmitting portion 620.

Here, the intensity of the light passing through the first transmitting portion 610 is larger than that of the light passing through the second transmitting portion 620. As a result, the first curing region 500a is larger than the second curing region 500b.

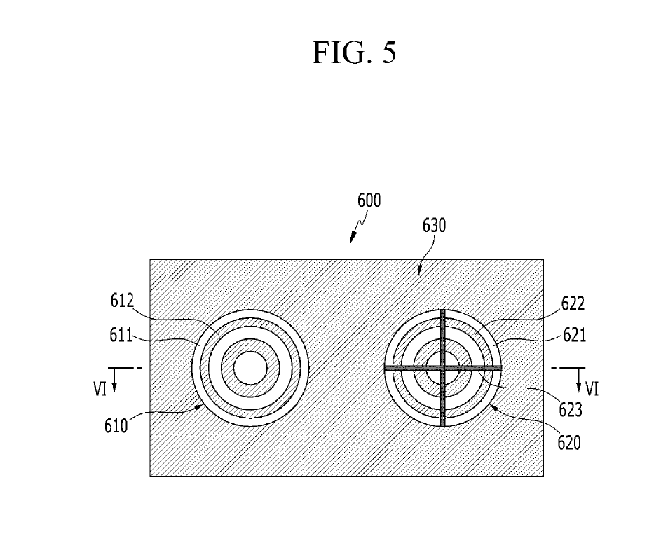

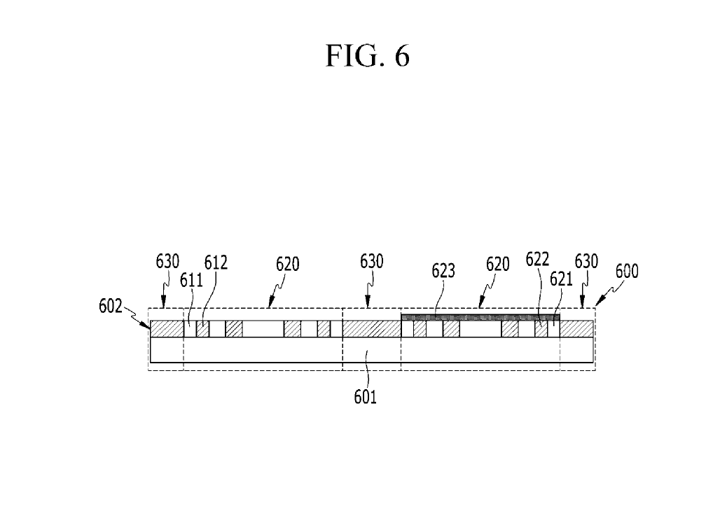

Next, a mask according to an exemplary embodiment of the present invention will be described in detail with reference to FIGS. 5 and 6.

FIG. 5 is a diagram schematically illustrating a plan view of a mask according to the exemplary embodiment of the present invention. FIG. 6 is a diagram illustrating an example of a cross section of the mask of FIG. 5 taken along line VI-VI.

Referring to FIGS. 5 and 6, the mask 600 according to the exemplary embodiment includes a transparent substrate 601 and a light blocking layer 602 disposed on the transparent substrate 601. Further, the mask 600 according to the exemplary embodiment includes a first transmitting portion 610, a second transmitting portion 620, and a light blocking portion 630.

In the light blocking portion 630, the light blocking layer 602 covers the entire surface of the transparent substrate 601. As a result, light does not pass through the light blocking portion 630.

In the first transmitting portion 610 and the second transmitting portion 620, the light blocking layer 602 covers only a part of the transparent substrate 601.

The first transmitting portion 610 includes a first transmitting region 611 that passes light and a first light blocking region 612 that blocks light. The first light blocking region 612 is a portion where the light blocking layer 602 is disposed, and the first transmitting region 611 is a portion where the light blocking layer 602 is not disposed (or has been removed). The first transmitting region 611 and the first light blocking region 612 are alternately arranged in a concentric form. Due to the arrangement, the light passing through the first transmitting portion 610 is diffracted to be collected at a predetermined distance. As a result, the light passing through the first transmitting portion 610 is incident to the photosensitive material layer 500 to form the first curing region 500a as illustrated in FIG. 4.

The second transmitting portion 620 includes a second transmitting region 621 transmitting the light, a second light blocking region 622 blocking the light, and a blocking member 623 blocking the light. The second light blocking region 622 is a portion where the light blocking layer 602 is disposed, and the second transmitting region 621 is a portion where the light blocking layer 602 is not disposed (or has been removed). The second transmitting region 621 and the second light blocking region 622 are alternately arranged in a concentric form. The blocking member 623 is disposed on the second transmitting region 621 and a part of the second light blocking region 622 and has a cross shape including a horizontal portion and a vertical portion. Due to this structure, light passing through the second transmitting portion 620 is diffracted by the second transmitting region 621 and the second light blocking region 622, but the diffracted light is partially blocked by the blocking member 623. As a result, the intensity of the light passing through the second transmitting portion 620 is smaller than that of the light passing through the first transmitting portion 610. Thus, the light passing through the second transmitting portion 620 is incident to the photosensitive material layer 500 to form the second curing region 500b having a smaller size than the first curing region 500a as illustrated in FIG. 4.

Meanwhile, since the light passing through the first transmitting portion 610 and the second transmitting portion 620 is diffracted, the intensity thereof is larger than that of non-diffracted light at certain distances. As a result, light efficiency is improved, and the first curing region 500a and the second curing region 500b may be more accurately formed, i.e. formed to have smaller features, as compared with forming the first curing region 500a and the second curing region 500b by the non-diffracted light.

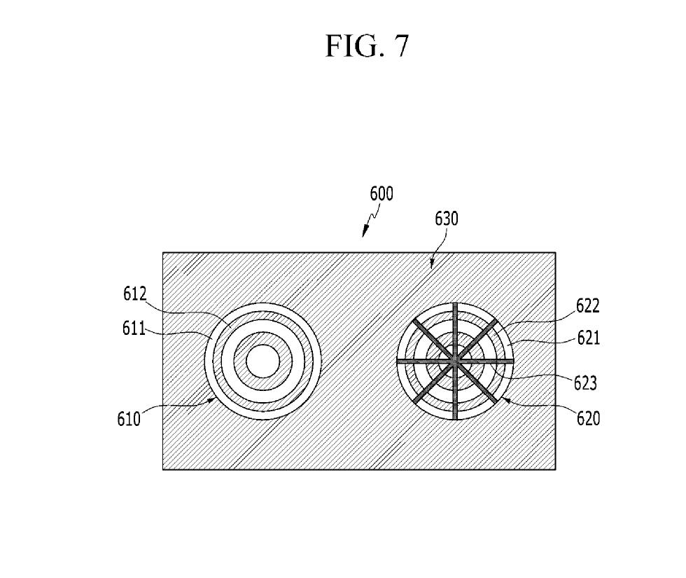

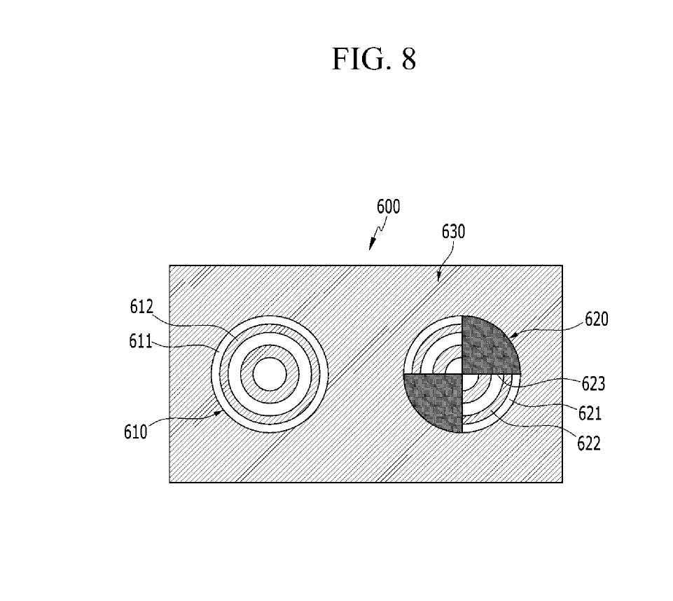

Next, a mask according to another exemplary embodiment of the present invention will be described in detail with reference to FIGS. 7 and 8.

FIG. 7 is a diagram schematically illustrating a plan view of a mask according to another exemplary embodiment of the present invention. Referring to FIG. 7, when the mask according to the exemplary embodiment is compared with the mask of FIG. 6, only a structure of the blocking member 623 is different and the remaining structures are substantially the same. Accordingly, description of like constituent elements will be omitted.

Still referring to FIG. 7, the blocking member 623 is disposed on the second transmitting region 621 and a part of the second light blocking region 622, and has a radial shape with spokes extending radially from a central hub. Due to this structure, light passing through the second transmitting portion 620 is diffracted by the second transmitting region 621 and the second light blocking region 622, but the diffracted light is partially blocked by the blocking member 623. As a result, the intensity of the light passing through the second transmitting portion 620 is smaller than that of the light passing through the first transmitting portion 610.

FIG. 8 is a diagram schematically illustrating a plan view of a mask according to yet another exemplary embodiment of the present invention. Referring to FIG. 8, when the mask according to this exemplary embodiment is compared with the mask of FIG. 6, only the structure of the blocking member 623 is different and the remaining structures are substantially the same. Accordingly, the description of like constituent elements will be omitted.

Referring to FIG. 8, the blocking member 623 is disposed on the second transmitting region 621 and a part of the second light blocking region 622, and has a plurality of fan shapes (wedge-shaped portions of a circle) which is spaced apart from each other. In the exemplary embodiment, the blocking member 623 blocks ½ of the second transmitting portion 620, but is not limited thereto and may block ¼ of the second transmitting portion 620 or ¾ of the second transmitting portion 620, or any other fractional amount that may be desired. Due to this structure, light passing through the second transmitting portion 620 is diffracted by the second transmitting region 621 and the second light blocking region 622, but the diffracted light is partially blocked by the blocking member 623. As a result, the intensity of the light passing through the second transmitting portion 620 is smaller than that of the light passing through the first transmitting portion 610.

It should be noted that embodiments of the invention include further configurations and modifications not shown above. For example, the transmitting portions are shown as circular with centers of area that are coincident, but may be of any other shape, such as elliptical, polygonal, or the like. Also, the light blocking and light transmitting regions need not be precisely concentric (e.g. their area centers need not be coincident) nor alternately arranged, and may be of any configuration and arrangement that allows for a desired amount of light to pass. Finally, the second transmitting portion is not limited to the configurations shown, and may be any shape and arrangement that reduces an intensity of light that passes through its corresponding light transmitting portion.

Referring to FIG. 9, a main spacer 320a and a sub spacer 320b are formed on the lower alignment layer 12 by developing the photosensitive material layer 500 with the first curing region 500a and the second curing region 500b. As a result, the first display panel 100 is completed.

During developing, the remaining photosensitive material layer 500 except for the first curing region 500a and the second curing region 500b is removed, the first curing region 500a forms the main spacer 320a, and the second curing region 500b forms the sub spacer 320b. As a result, the length of the main spacer 320a is greater than that of the sub spacer 320b.

As such, the main spacer 320a and the sub spacer 320b having different lengths may be simultaneously formed by using the mask 600 including the first transmitting portion 610, the second transmitting portion 620, and the light blocking portion 630. As a result, the process is simplified.

Referring to FIG. 2, the second display panel 200 is formed by forming the light blocking member 220, the planarization layer 250, and the common electrode 270 on the second insulation substrate 210, the first display panel 100 and the second display panel 200 are assembled together, and then the liquid crystal layer 3 is formed by injecting the liquid crystal material including the liquid crystal molecules 31 between the first display panel 100 and the second display panel 200. Further, before assembling the first display panel 100 and the second display panel 200, the liquid crystal layer 3 is formed by dropping the liquid crystal material, including the liquid crystal molecules 31, between the first display panel 100 and the second display panel 200, and then the first display panel 100 and the second display panel 200 may be affixed to each other.

In this case, the longer main spacer 320a contacts the second display panel 200 to uniformly maintain a gap between the first display panel 100 and the second display panel 200, while the shorter sub spacer 320b remains spaced apart from the second display panel 200.

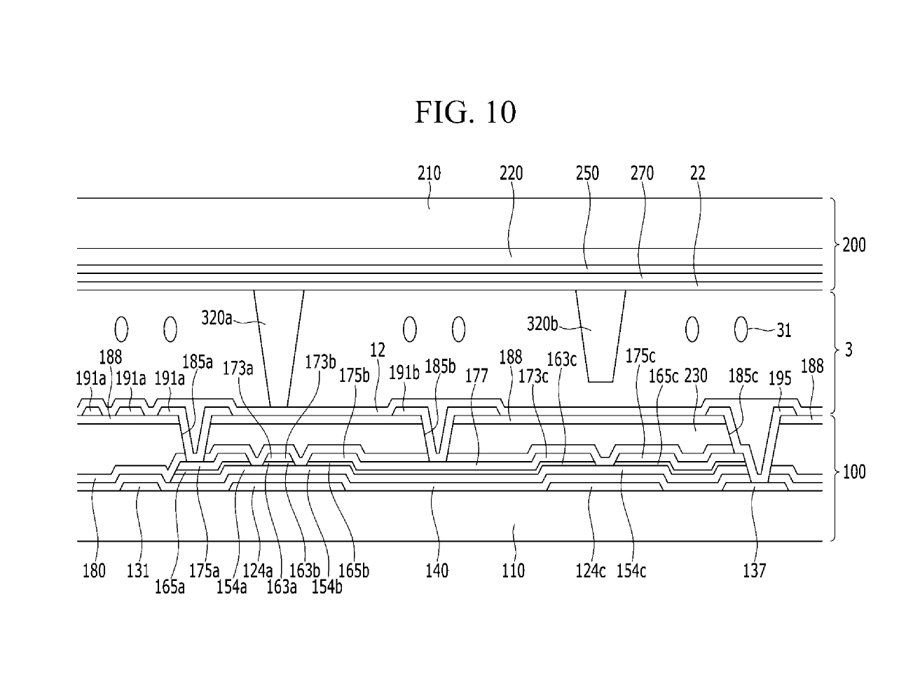

Alternatively, the main spacer 320a and the sub spacer 320b may instead be disposed on the second display panel 200, and this structure will be described with reference to FIG. 10.

FIG. 10 is a diagram illustrating an example of a cross section of a liquid crystal display according to another exemplary embodiment of the present invention. Referring to FIG. 10, when the liquid crystal display according to this exemplary embodiment is compared with the liquid crystal display of FIG. 2, positions where the main spacer 320a and the sub spacer 320b are disposed are different from each other, while the remaining structures are substantially the same. Accordingly, the description of like constituent elements will be omitted.

The main spacer 320a and the sub spacer 320b are disposed on the second display panel 200. In detail, the main spacer 320a and the sub spacer 320b are disposed on the upper alignment layer 22.

The longer main spacer 320a contacts the first display panel 100. The main spacer 320a serves to uniformly maintain a gap between the first display panel 100 and the second display panel 200. The main spacer 320a may have elasticity and may be compressed by external force and then restored to its original state once the force is removed.

The shorter sub spacer 320b remains spaced apart from the first display panel 100. The sub spacer 320b contacts the second display panel 200 to distribute the force applied to the main spacer 320a when external compressive force having at least a predetermined value is applied. As a result, the sub spacer 320b may prevent the main spacer 320a from being damaged by this external force.

The main spacer 320a and the sub spacer 320b may be formed by forming the photosensitive material layer 500 on the upper alignment layer 22, exposing the photosensitive material layer 500 by using the mask 600 including the first transmitting portion 610, the second transmitting portion 620, and the light blocking portion 630, and then developing the photosensitive material layer 500, as described in FIGS. 4 to 9 above.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Furthermore, different features of the various embodiments, disclosed or otherwise understood, can be mixed and matched in any manner to produce further embodiments within the scope of the invention.

### DESCRIPTION OF SYMBOLS

| | |
|---|---|
| 100: First display panel | 121: Gate line |

124a, 124b, 124c: First, second and third gate electrode

| | |
|---|---|
| 131: Reference voltage line | 137: Reference electrode |

154a, 154b, 154c: First, second and third semiconductor

| | |
|---|---|
| 171: Data line | 171a, 171b: First and second data line |

173a, 173b, 173c: First, second and third source electrode
175a, 175b, 175c: First, second and third drain electrode

| | |
|---|---|
| 188: Overcoat | 191: Pixel electrode |

191a, 191b: First and second subpixel electrode

| | |
|---|---|
| 200: Second display panel | 230: Color filter |
| 270: Common electrode | 320a: Main spacer |
| 320b: Sub spacer | 600: Mask |
| 601: Transparent substrate | 602: Light blocking layer |
| 610: First transmitting portion | 620: Second transmitting portion |

611, 621: First and second transmitting region
612, 622: First and second light blocking region

| | |
|---|---|
| 623: Blocking member | 630: Light blocking portion |

What is claimed is:

1. A mask, comprising:
a transparent substrate; and
a light blocking layer disposed on the transparent substrate,
wherein the transparent substrate includes a first transmitting portion and a second transmitting portion each configured to pass light therethrough, and a light blocking portion configured to block light,
wherein the first transmitting portion includes a first transmitting region configured to pass light therethrough and a first light blocking region configured to block light, and a center of area of the first transmitting region and a center of area of the first light blocking region substantially coincide,
wherein the second transmitting portion includes a second transmitting region configured to pass light therethrough and a second light blocking region configured to block light, and a center of area of the second transmitting region and a center of area of the second light blocking region substantially coincide, and
wherein the first transmitting portion is configured to pass light having a first intensity, and the second transmitting portion is configured to pass light having a second intensity, the first intensity being greater than the second intensity.

2. The mask of claim 1, wherein the light blocking layer is disposed on the light blocking portion, the first light blocking region, and the second light blocking region.

3. The mask of claim 2, wherein the second transmitting portion further includes a blocking member configured to block light, and
the blocking member is disposed on parts of both the second transmitting region and the second light blocking region.

4. The mask of claim 3, wherein the blocking member has a cross shape including a first portion and a second portion oriented substantially perpendicular to the first portion.

5. The mask of claim 3, wherein the blocking member has a center and members extending radially from the center.

6. The mask of claim 3, wherein the blocking member has a plurality of fan-shaped structures spaced apart from each other.

7. A method of manufacturing a liquid crystal display, comprising:
forming a gate line on a first insulation substrate;
forming a gate insulating layer on the first insulation substrate and the gate line;
forming a semiconductor on the gate insulating layer;
forming a data line on the semiconductor, the data line including a source electrode and a drain electrode facing the source electrode;
forming a passivation layer on the gate insulating layer, the data line, and the drain electrode;
forming a lower alignment layer on the passivation layer;
forming a photosensitive material layer on the lower alignment layer;
forming a first curing region and a second curing region by exposing the photosensitive material layer using a mask, so that the second curing region has a size smaller than a size of the first curing region; and
forming a main spacer and a sub spacer by developing the photosensitive material layer,
wherein a length of the main spacer is larger than that of the sub spacer,
wherein the mask includes:
a transparent substrate, and
a light blocking layer disposed on the transparent substrate,
wherein the transparent substrate includes a first transmitting portion and a second transmitting portion each configured to pass light therethrough, and a light blocking portion configured to block light, and
wherein the forming a first curing region and a second curing region further comprises:
forming the first curing region by passing light through the first transmitting portion, and
forming the second curing region from light passing through the second transmitting portion.

8. The method of claim 7, wherein the forming a main spacer and a sub spacer further comprises forming the main spacer from the first curing region and forming the sub spacer from the second curing region.

9. The method of claim 8, wherein the photosensitive material layer has negative photosensitivity.

10. The method of claim 7, wherein the first transmitting portion includes a first transmitting region configured to transmit light and a first light blocking region configured to block light, and the first transmitting region and the first light blocking region are positioned in alternating and concentric manner.

11. The method of claim 10, wherein the second transmitting portion includes a second transmitting region configured to transmit light and a second light blocking region configured to block light, and the second transmitting region and the second light blocking region are positioned in alternating and concentric manner.

12. The method of claim 11, wherein the light blocking layer is positioned on the light blocking portion, the first light blocking region, and the second light blocking region.

13. The method of claim 12, wherein the second transmitting portion further includes a blocking member configured to block light, and
the blocking member is disposed on parts of both the second transmitting region and the second light blocking region.

14. The method of claim 13, wherein the blocking member has a cross shape including a first portion and a second portion oriented substantially perpendicular to the first portion.

15. The method of claim 13, wherein the blocking member has a center and members extending radially from the center.

16. The method of claim 13, wherein the blocking member has a plurality of fan-shaped structures spaced apart from each other.
